(19) United States
(12) Patent Application Publication
(10) Pub. No.: US 2008/0107998 A1
(43) Pub. Date: May 8, 2008

(54) NEAR-FIELD EXPOSURE METHOD AND DEVICE MANUFACTURING METHOD USING THE SAME

(75) Inventors: Yasuhisa Inao, Tokyo (JP); Takako Yamaguchi, Kawasaki-shi (JP); Toshiki Ito, Kawasaki-shi (JP); Natsuhiko Mizutani, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/740,604

(22) Filed: Apr. 26, 2007

(30) Foreign Application Priority Data
Apr. 27, 2006 (JP) 122995/2006

(51) Int. Cl. G03F 9/00

(52) U.S. Cl. 430/322

(57) ABSTRACT

A near-field exposure method in which a light blocking film with an opening having an opening width not greater than a wavelength size of exposure light is contacted to an object to be exposed and in which light from an exposure light source is projected on the light blocking film so that a pattern based on the opening of the light blocking film is formed on the object to be exposed, by use of near-field light produced at the opening, wherein the object to be exposed is prepared by a process that includes (i) a step of providing, upon a substrate having surface irregularity, a shape buffering layer so as to fill the surface irregularity thereof to thereby flatten the surface of the substrate, (ii) a step of providing, upon the shape buffering layer, a light reflecting layer for reflecting the exposure light, and (iii) a step of providing a photosensitive resist layer upon the light reflecting layer, and wherein the exposure is carried out to the object so prepared.

### FIELD OF THE INVENTION AND RELATED ART

This invention relates to a near-field exposure method and a device manufacturing method using such exposure method.

Lithographic technology has been advanced and diversified, and various exposure methods haven been proposed as emerging lithographic technology, looking for further potentials.

An example is U.S. Pat. No. 6,171,730 which proposes an exposure method based on optical near-field, as one exposure method that enables microprocessing beyond the diffraction limit of light.

In the near-field exposure method disclosed in this patent document, a mask is made of an elastic material. The mask is elastically deformed to follow the resist surface shape such that, while the whole mask surface is closely contacted to the resist surface, the exposure is carried out by use of optical near-field.

Another example is a fine pattern forming method disclosed in Japanese Laid-Open Patent Application No. S61-075525, wherein a method of forming a pattern by use of triple-layer resist has been proposed. In this method, if a bedding substrate has surface irregularity (surface level difference), a triple-layer resist that comprises a lower resist layer, an intermediate layer on the lower resist layer, and an upper resist layer on the intermediate layer, is provided on the bedding substrate, and then a fine pattern is formed thereon.

Recently, extraordinarily high precisions have been required in the microprocessing process and, with regard to the fine-pattern forming method based on the lithography as well, further improvements of transfer precision are strongly desired.

However, if a bedding substrate having surface irregularity is used, uneven exposure may be inevitable in the near-field exposure method described above. Even if the pattern forming method using a triple-layer resist described above is applied, it would be difficult to fully meet the requirements of extraordinarily high precision in the microprocessing process.

### SUMMARY OF THE INVENTION

In accordance with an aspect of the present invention, there is provided a near-field exposure method in which a light blocking film with an opening having an opening width not greater than a wavelength size of exposure light is contacted to an object to be exposed and in which light from an exposure light source is projected on the light blocking film so that a pattern based on the opening of the light blocking film is formed on the object to be exposed, by use of near-field light produced at the opening, characterized in that: the object to be exposed is prepared by a process that includes (i) a step of providing, upon a substrate having surface irregularity, a shape buffering layer so as to fill the surface irregularity thereof to thereby flatten the surface of the substrate, (ii) a step of providing, upon the shape buffering layer, a light reflecting layer for reflecting the exposure light, and (iii) a step of providing a photosensitive resist layer upon the light reflecting layer, and the exposure is carried out to the object so prepared.

In accordance with another aspect of the present invention, there is provided a near-field exposure method in which a light blocking film with an opening having an opening width not greater than a wavelength size of exposure light is contacted to an object to be exposed and in which light from an exposure light source is projected on the light blocking film so that a pattern based on the opening of the light blocking film is formed on the object to be exposed, by use of near-field light produced at the opening, characterized in that: the object to be exposed is prepared by a process that includes (i) a step of providing, upon a substrate having surface irregularity, a function layer having a function as a shape buffering layer and a function as a light reflecting layer for reflecting the exposure light, so as to fill the surface irregularity thereof to thereby flatten the surface of the substrate, and (ii) a step of providing a photosensitive resist layer upon the function layer, and the exposure is carried out to the object so prepared.

In accordance with a further aspect of the present invention, there is provided a device manufacturing method, including a process of producing a device by use of a near-field exposure method as recited above.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1A and 1B show a structural example of a near-field exposure mask used in the present invention, wherein FIG. 1A is a plan view and FIG. 1B is a sectional view.

FIGS. 2A-2D are schematic views, respectively, for explaining the principle of coating procedure for forming a shape buffering layer, a light reflecting layer and an upper resist layer in accordance with the present invention.

FIGS. 3A-3F are schematic views, respectively, for explaining the coating processes for forming a shape buffering layer, a light reflecting layer and an upper resist layer, in Example 1 of the present invention.

FIG. 4 is a schematic view for explaining the exposure process for performing the patterning based on near-field exposure, in Example 1 of the present invention.

FIGS. 5A-5F are schematic views, respectively, for explaining the processes for transferring a pattern to a resist film by near-field exposure, in Example 1 of the present invention.

FIGS. 6A-6D are schematic views, respectively, for explaining a structural example that uses a material having a function as a shape buffering layer and a function as a light reflecting layer, in Example 2 of the present invention.

FIG. 7 is a graph for explaining the result of calculation of light intensity distribution produced when light is incident on a near-field exposure mask, in a case where the photoresist film has a thickness of 160 nm.

FIG. 8 is a graph for explaining the result of calculation of light intensity distribution produced when light is incident on a near-field exposure mask, in a case where the photoresist film has a thickness of 220 nm.

FIG. 9 is a schematic view for explaining thickness distribution when a photoresist film is applied to a substrate having surface irregularity.

FIG. 10 is a graph for explaining the contrast of light intensity distribution with respect to the resist thickness, in a case where a slit is formed with a pitch of 90 nm.

### DESCRIPTION OF THE PREFERRED EMBODIMENTS

The inventors of the subject application have diligently made investigations and found that one factor that may cause exposure unevenness as a result of surface irregularity or differences of reflectance of the substrate in the near-field exposure method, is that the distribution of near-field light changes due to the difference in optical path length of exposure light from the near-field exposure mask to the substrate surface.

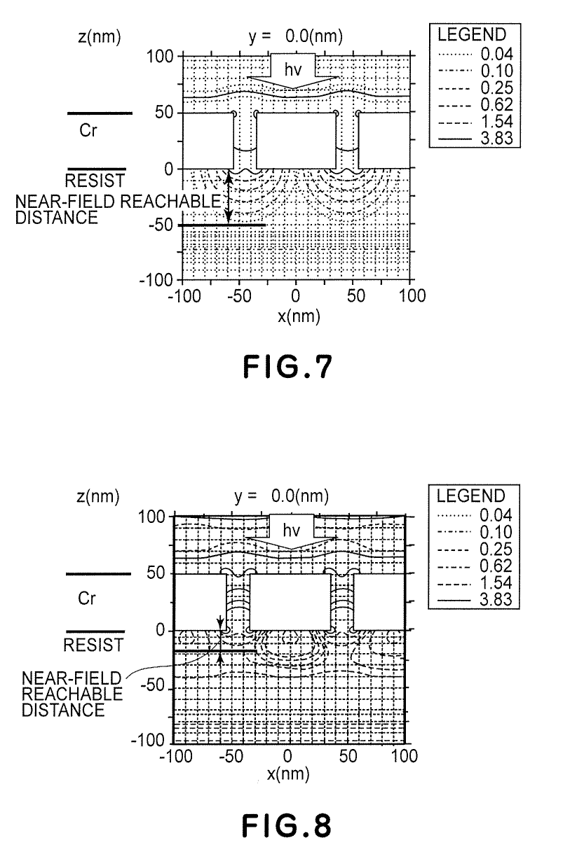

More specifically, as shown in comparative examples of FIGS. 7 and 8, when a mask is contacted to a substrate having a resist coating and light is incident thereon, and if the resist film thickness is different, the distribution of near-field light produced in the resist film is different.

In order to provide an explanation to such phenomenon, the inventors have made calculations on the distribution of near-field light leaking from the near-field exposure mask. The light intensity distributions shown in FIGS. 7 and 8 are based on the calculations made in accordance with the finite differential time domain method (FDTD method).

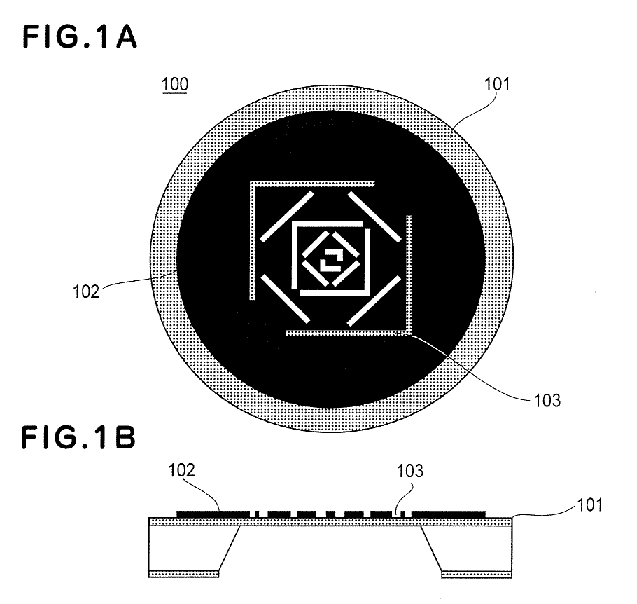

A near-field exposure mask 100 shown in FIG. 1 comprises a mask base material 101 made by a silicon nitride (SiN) film having a refractive index 1.9 and a thickness 500 nm, as well as a light blocking material 102 formed on the mask base material for blocking exposure light and made by a chromium (Cr) film having a thickness 50 nm. The Cr light blocking material is formed with fine slits (openings) of nm order. These fine slits (openings) have an opening width not greater than the wavelength size of the exposure light, but the length of the openings in their longitudinal direction may be longer than the wavelength of the exposure light.

The results of calculation to be described below are based on an example wherein the Cr light blocking film has fine slits of a width 20 nm, which are arrayed periodically at a pitch of 90 nm.

The mask was closely contacted to a photoresist on a silicon substrate. The calculations were carried out with respect to a light source of the wavelength of i-line which is 365 nm in a vacuum ambience.

An example of calculation results is illustrated in FIG. 7. More specifically, FIG. 7 shows a light intensity distribution produced under the condition that a photoresist film of a thickness 160 nm is formed on the surface of a flat silicon substrate and, while the near-field mask is closely contacted to the photoresist, light of 365 nm is projected thereto from the near-field exposure mask side.

It is seen from this calculation result that the near-field light exists up to a distance of about 50 nm from the mask surface.

Another example is illustrated in FIG. 8. FIG. 8 shows a light intensity distribution produced under the condition that a photoresist film of a thickness 220 nm is formed on the surface of a flat silicon substrate and, while the near-field mask is closely contacted to the photoresist, light of 365 nm is projected thereto from the near-field exposure mask side.

It is seen from this calculation result that the near-field light exists up to a distance of about 20 nm from the mask surface.

The examples of FIGS. 7 and 8 differ from each other only in the thickness of the photoresist film formed on the surface of silicon substrate. Thus, from these results, it has been confirmed that, if the resist film thickness, that is, the distance from the near-field exposure mask surface to the silicon substrate surface where light is reflected changes, the distance reachable by the near-field light leaking from the mask openings changes.

This can be confirmed also on the basis of comparison of contrast of the light intensity at a plane spaced from the mask by a certain distance. Here, the term “contrast” can be defined as follows. When in FIGS. 7 and 8 the largest value of light intensity, with respect to X direction, at a certain value along the axis of ordinate (Z) is denoted by Imax while the smallest value is denoted by Imin, the contrast C is defined by:

C=(Imax−Imin)/(Imax+Imin)

FIG. 10 is a graph for explaining the contrast, wherein the thickness of photoresist film is taken on the axis of abscissa and the contrast is taken on Y axis. Solid-line curve in this graph depicts values at Z=10 nm, broken-line curve depicts values at Z=20 nm, and dash-and-dot-line curve depicts values at Z=30 nm.

It is seen from this graph that, if the thickness of a photoresist film changes, the contrast changes quite notably. And, from this, it is seen that the light intensity distribution changes heavily in dependence upon the thickness of the photoresist film.

From the results of calculations made to these examples, the inventors have obtained the following findings.

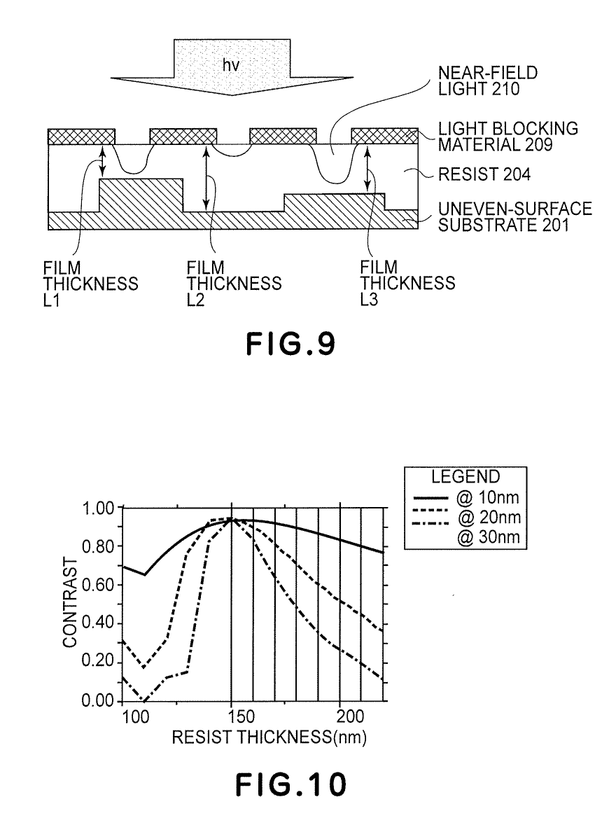

If as shown in FIG. 9 a substrate 201 on which a photoresist film 204 is formed has surface irregularity, the thickness of the photoresist film 204 is not even throughout the whole surface of the substrate 201. Rather, the thickness is different at different points along the substrate surface. Denoted at 209 in FIG. 9 is a light blocking film that constitutes the mask, and denoted at 210 is near-field light.

Since the thickness of the photoresist film 204 on the substrate 201 is different and uneven, the result would be that the near-field light reachable distance (distance reachable by leaking exposure light) is different, as has been described with reference to FIGS. 7 and 8.

This would result in that, when the exposed photoresist film or substrate is developed, the pattern produced thereby has different depths or shapes. Since the photoresist pattern after being developed is used in subsequent steps such as plating or etching, the phenomenon described above shows possible difficulties of applying near-field exposure to substrates having surface irregularity.

Investigating these results carefully, the inventors have finally found that the inconveniences described above can be removed or significantly reduced by providing a shape buffering layer on a substrate having surface irregularly so as to fill the surface irregularly of the substrate to thereby flatten the substrate surface, and by providing a light reflecting layer on the shape buffering layer and a photoresist layer on the light reflecting layer.

Since the light reflecting layer is formed on the shape buffering layer being flattened, the photoresist film provided on the light reflecting layer which is flat would have a quite even thickness. Furthermore, due to the provision of the light reflecting layer, light does not penetrate into the shape buffering layer. As a result, any changes in the near-field distribution which otherwise will be caused by uneven thickness of the photoresist film, being different at different points on the substrate surface, can be well suppressed, such that uniform exposure by near-field light can be accomplished throughout the whole mask surface. Hence, production of very fine and high-precision patterns is attainable.

The present invention may be embodied as a near-field exposure method in which a light blocking film with an opening having an opening width not greater than a wavelength size of exposure light is contacted to an object to be exposed and in which light from an exposure light source is projected on the light blocking film so that a pattern based on the opening of the light blocking film is formed on the object to be exposed, by use of near-field light produced at the opening. An important feature may reside in that the object to be exposed is prepared by a process that includes (i) a step of providing, upon a substrate having surface irregularity, a shape buffering layer so as to fill the surface irregularity thereof to thereby flatten the surface of the substrate, (ii) a step of providing, upon the shape buffering layer, a light reflecting layer for reflecting the exposure light, and (iii) a step of providing a photosensitive resist layer upon the light reflecting layer.

The present invention may be embodied as a near-field exposure method wherein the object to be exposed is prepared by a process that includes (i) a step of providing, upon a substrate having surface irregularity, a function layer having a function as a shape buffering layer and a function as a light reflecting layer for reflecting the exposure light, so as to fill the surface irregularity thereof to thereby flatten the surface of the substrate, and (ii) a step of providing a photosensitive resist layer upon the function layer.

In one preferred form of the present invention, the surface irregularity of the substrate may have a surface level difference (height) 0.05 times or more as large as the wavelength of the exposure light within the photosensitive resist layer and, as a result of the flattening, the surface level difference of the surface irregularity of the substrate may be substantially reduced to a value less than 0.05 times as large as the wavelength of the exposure light.

In one preferred form of the present invention, the photosensitive resist layer may be provided by one layer of a multilayer-resist material having multiple layers.

In one preferred form of the present invention, the multilayer-resist material may comprise a lower resist layer adapted to be removed by plasma etching, an intermediate layer formed on the lower resist layer and having resistance to plasma etching, and an upper resist layer that provides the photosensitive resist layer.

In one preferred form of the present invention, the multilayer-resist material may comprise a lower resist layer adapted to be removed by plasma etching and an upper resist layer formed on the lower resist layer and having resistance to plasma etching.

In one preferred form of the present invention, the shape buffering layer may have a thickness in a range from twice to ten times as large as the surface level difference of the surface irregularity of the substrate.

In one preferred form of the present invention, the light reflecting layer may have a thickness in a range from 0.1 to 1 times as large as the thickness of the shape buffering layer.

Next, an embodiment of the present invention wherein the invention is embodied specifically in accordance with the findings described hereinbefore, will be explained.

In FIG. 1, a near-field exposure photomask 100 comprises a mask base material 101 which is transparent with respect to the wavelength of a light source, and a light blocking material 102 having a function for blocking the wavelength of the light source. The light blocking material is provided with fine-opening patterns (openings) 103 having an opening width of a size not greater than the wavelength of the light source.

This photomask is used in the following manner: it is closely contacted to a substrate (object to be exposed) being coated with a photoresist and exposure light is projected thereto from the photomask side, so that the mask pattern is lithographically transferred to the photoresist. The photoresist used here is a material which is sensitive to light and, through an appropriate development treatment, a pattern is produced thereby.

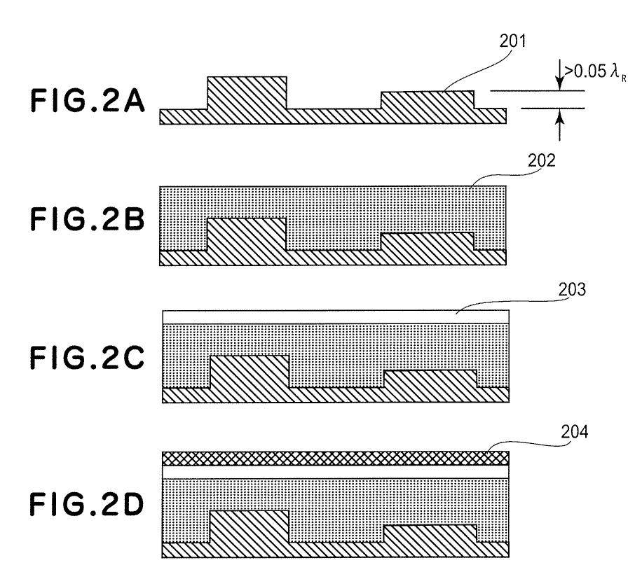

Referring to FIGS. 2A-2D, this embodiment is applied to an exposure method for exposing a substrate 201 having surface irregularity. It has a feature in respect to the photoresist layer to be formed on the substrate.

Here, the surface irregularity of the substrate refers to unevenness having a surface level difference not less than 0.05λ (λ is the effective wavelength of exposure light within the photoresist) (FIG. 2A), in this example, and the material that defines the surface level difference has a refractive index different from that of the photoresist material.

A shape buffering layer 202 made of a material having good filling property with respect to the substrate, is provided on the substrate with a thickness not less than the surface level difference of the surface irregularity. The surface of the shape buffering layer is flattened thereby (FIG. 2B). Here, the word “flattened” refers to a state in which the magnitude of the surface irregularity of the shape buffering layer has been reduced to less than 0.05λ.

The shape buffering layer may be formed by applying, through a spin coating method, an organic material solved in a solvent. For example, polyimide solved in an organic solvent such as n-methylpyrolidone or Y-butyllactone or the like may be applied by spin coating, or a photoresist material used in lithography may be applied by spin coating.

Alternatively, a film may be formed on the substrate so as to fill the surface irregularity thereof while making the film surface flat, e.g., by forming a film by using a sputtering process to provide flat film surface.

As regards the material for the shape buffering layer, any materials may be used provided that it has lower resistance to dry etching as compared with the light reflecting layer and/or the upper resist layer (to be described later) so that it can be dry-etched while using the light reflecting layer and/or the upper resist layer as an etching mask. For example, SiO₂ or organic material such as polyimide or photoresist may be used. It should be noted here that the film forming methods or film materials mentioned hereinbefore are merely examples, and the present invention is not limited to use of them.

After the flattening, a light reflecting layer 203 for reflecting the exposure light is provided on the shape buffering layer 202 (FIG. 2C). As regards the material of this light reflecting layer, metal material, semiconductor material or organic material may be used appropriately.

The light reflecting layer may be formed in accordance with a method of forming a silicon film by use of a sputtering process, or by a method of forming a chromium film by a vacuum vapor deposition process.

Alternatively, a method of forming a film by applying, through a spin coating process, polythiophene (conductive high polymer) solved in an organic solvent, or a method of doping perchloric ion in polythiophene, may be used.

As regards the light reflecting layer 203 used here, it is not limited to the materials described above. It may be made of any materials provided that the light can reflect at the interface between the light reflecting layer and the upper resist layer to be described below.

Then, upon the light reflecting layer 203 thus produced, a film having photosensitivity to exposure light is provided as an upper resist layer 204 which is going to be exposed by near-field light (FIG. 2D).

The upper resist layer may be formed by using a method of forming, through spin coating, a single layer of photoresist film used in the photolithography. Alternatively, a dual-layer resist method wherein an upper layer is made of a photoresist material containing silicon atoms and having photosensitivity while a lower layer is made of an organic material, may be used. As a further alternative, a pattern-forming-material producing method used in the photolithography such as triple-layer resist method may be used. The triple-layer resist method is a method in which, as an example, an upper layer is made of photoresist having photosensitivity to exposure light, an intermediate layer is made of spin-on glass (SOG), and a lower layer is made of an organic material.

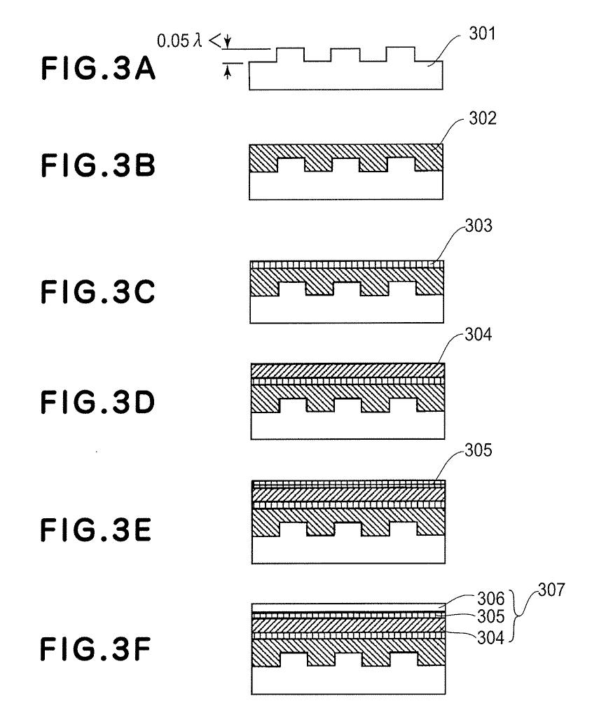

Although these materials are mentioned as an example wherein it is photosensitized by exposure light and, through development, a pattern is produced thereby, any other materials may be used provided that the material property can be changed by exposure light. As an example, the upper layer resist may be produced in accordance with a triple-layer resist method which will be described below with reference to the example of FIG. 3.

In accordance with this embodiment of the present invention as described above, a shape buffering layer is provided on a substrate having surface irregularity so as to fill the surface irregularity thereof to thereby flatten the substrate surface, and a light reflecting layer is provided on the shape buffering layer and then a photoresist layer is provided on the light reflecting layer. By doing so, uniform exposure throughout the whole mask surface is assured.

Namely, with the procedure described above, the thickness of the photoresist film from the light reflecting layer surface, that reflects the exposure light, to the photoresist film surface becomes quite even. Therefore, any change of the near-field distribution which otherwise results from different thicknesses of photoresist film at different points on the substrate, can be well suppressed, such that uniform exposure throughout the whole mask surface can be accomplished.

Now, specific examples of the present invention will be described below.

### EXAMPLE 1

With regard to Example 1, a near-field exposure method according to the present invention will be explained.

FIGS. 3A-3F are schematic views for explaining the coating processes for providing a shape buffering layer, a light reflecting layer and an upper resist layer in this example.

In this example, first of all, a silicon substrate 301 having surface irregularity defined by a line-and-space of 50 nm depth, is prepared (FIG. 3A). Here, the surface irregularity to be handled by the present invention is, generally, those having a height (surface level difference) in a range of 50 nm to 100 nm.

Next, onto this silicon substrate 301, polyimide is applied by a spin coating process to a thickness of 150-200 nm, to provide a shape buffering layer 302.

Subsequently, the substrate is placed on a hot plate having a temperature raised preferably to 200-400° C., more preferably, to 300-350° C., to set the polyimide.

With this procedure, the surface irregularity of the silicon substrate 301 is filled and the polyimide surface is flattened (FIG. 3B).

Then, a silicon film is formed on it by a sputtering process to a thickness 30 nm, to provide a light reflecting film 303 (FIG. 3C).

After this, a triple-layer resist 307 is provided as an upper resist layer upon the light reflecting layer.

To this end, initially, a positive type photoresist is applied by a spin coating method, to provide a lower layer 304 of the triple-layer resist, and then it is heated at 120° C. to remove the photosensitivity. The lower layer in this example has a thickness 120 nm (FIG. 3D).

Subsequently, a film of SiO₂ is formed with a thickness 20 nm, by a sputtering method, to provide an intermediate layer 305 of the triple-layer resist (FIG. 3E).

Furthermore, a chemical amplification type positive photoresist having sensitivity to i-line (wavelength 365 nm) of the bright line of an Hg lamp is formed by spin coating with a thickness 20 nm, to provide an upper layer 306 of the triple-layer resist (FIG. 3F).

With the procedure described above, a material to be exposed can be evenly produced (as the upper resist layer) on the flat light reflecting layer, with a total thickness of 160 nm.

Although the near-field light reaches up to about 50 nm distance from the mask surface, since the thickness of the upper layer of the triple-layer resist is 20 nm, thinner than it, the material up to the bottom of the upper resist layer (up to the interface between the upper resist layer and the intermediate layer) can be exposed. Also, the latitude to any change in exposure amount is large.

Next, the exposure process for patterning, through near-field exposure, a substrate having surface irregularity and formed with a shape buffering layer, a light reflecting layer and a triple-layer resist, will be explained.

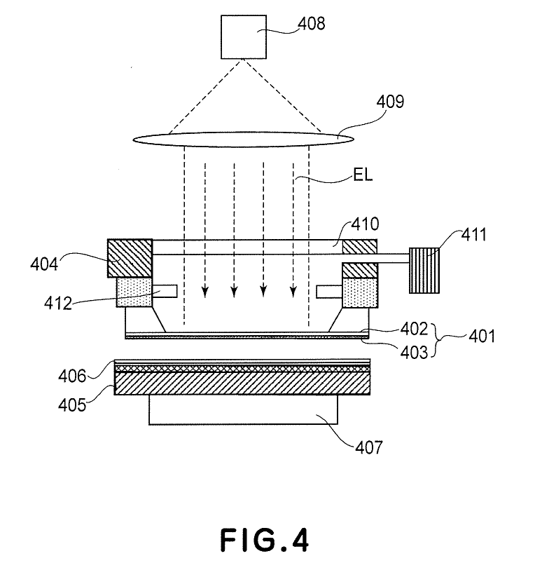

FIG. 4 is a schematic view of an exposure apparatus, for explaining this exposure process.

In FIG. 4, denoted at 401 is a near-field exposure photomask. The photomask 401 has a front surface (shown at bottom in FIG. 4) placed to face the outside of a pressure adjusting container 404, and a back surface (shown at top in FIG. 4) placed to face the inside of the pressure adjusting container 404. The inside pressure of the pressure adjusting container 404 can be adjusted through a pressure adjusting means 411.

The object to be exposed in this example comprises a substrate 405 having a resist film 406 formed thereon. The resist film has a five-layer structure, including a shape buffering layer, formed on the substrate 405 surface, a light reflecting layer and a triple-layer resist. The combined structure of resist film 406 and substrate 405 is mounted on a stage 407 and, by moving the stage 407 in x-y plane, the substrate 405 is relatively and two-dimensionally aligned along the mask surface, with respect to the near-field exposure mask 401.

Subsequently, the stage 407 is moved in a direction of a normal to the mask surface, so that the photomask 401 comes very close to the resist film 406 on the substrate 405.

After this, the pressure inside the pressure adjusting container 404 is adjusted by the pressure adjusting means 411, so that the front surface of the near-field exposure mask 401 and the resist film 406 surface on the substrate come close to each other until, throughout these surfaces, the clearance between them becomes equal to 100 nm or less. Here, preferably, the exposure mask 401 and the resist film 406 are closely contacted to each other. However, they may be in partial or local contact. Furthermore, what is required here is that the clearance between them should be not greater than 100 nm.

After this, exposure light EL is emitted from an exposure light source 408 and it is transformed into parallel light by means of a collimator lens 409. The exposure light then goes through a glass window 410 and enters the pressure adjusting container 404, and it irradiates the near-field exposure mask 410 from its back side (shown at top in FIG. 4).

With this illumination of exposure light, the resist film 406 can be exposed by near-field which is produced adjacent the fine openings of the front surface of the near-field exposure mask 401.

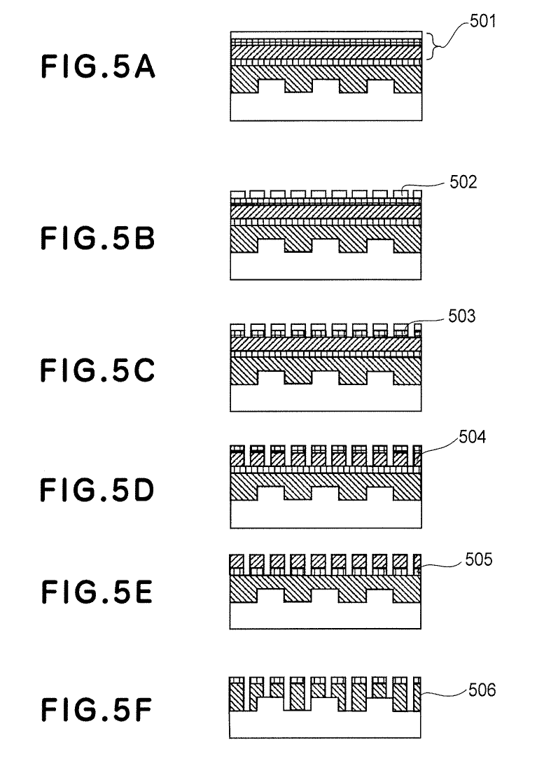

Next, the procedure for transferring a pattern to a resist film, having been exposed by near-field as described above, will be explained. FIGS. 5A-5F are schematic views for explaining this procedure.

In FIG. 5A, denoted at 501 is a resist film having been exposed by near-field in accordance with the procedure described hereinbefore. The upper laser 502 of the exposed triple-layer resist is then developed, by dipping, by using an aqueous solution of 2.38% TMAH, whereby a pattern is formed (FIG. 5B). Then, by using this upper layer of the triple-layer resist as an etching mask, dry etching is carried out through a mixed gas of SF₆ and CHF₃, whereby a pattern is transferred to the intermediate layer 503 which comprises a SiO₂ layer (FIG. 5C).

Then, by using this intermediate layer as an etching mask, the lower layer of the triple-layer resist is etched through a mixed gas of oxygen and argon, whereby a pattern is transferred to the lower layer 504 of the triple-layer resist (FIG. 5D).

Subsequently, by using the pattern of the upper resist layer formed through the procedure described above, according to the triple-layer resist method, the silicon of the light reflecting layer 505 is dry etched through a mixed gas of SF₆ and CHF₃, whereby a pattern is transferred thereto (FIG. 5E).

After this, by using the silicon of light reflecting layer 505 as an etching mask, polyimide of the lower layer 506 is dray etched through a mixed gas of oxygen and argon, whereby a pattern is transferred thereto (FIG. 5F).

With the processes described above, the pattern of the near-field exposure mask can be evenly transferred onto the substrate having surface irregularity.

By transferring the resist pattern produced in this manner to substrates of various materials, structures of various shapes having a size not greater than 100 nm can be produced.

In accordance with the exposure method of the present invention, various microdevices having structural members of different sizes, not greater than 100 nm, can be produced. Examples are as follows:

(1) a quantum dot laser device with a structure having GaAs quantum dots of 50 nm size arrayed two-dimensionally at 50 nm intervals;

(2) a sub wavelength element (SWS) structure with antireflection function, having conical SiO₂ structures of 50 nm size arrayed two-dimensionally at 50 nm intervals on a SiO₂ substrate;

(3) a photonic crystal optics device or plasmon optical device in which structures of 100 nm size, made of GaN or metal, are arrayed two-dimensionally and periodically at 100 nm intervals;

(4) a biosensor or a micro-total analyzer system (PTAS) based on local plasmon resonance (LPR) or surface enhancement Raman spectrum (SERS) in which Au fine particles of 50 nm size are arrayed two-dimensionally upon a plastic substrate at 50 nm intervals; and

(5) a nano-electromechanical system (NEMS) device such as SPM probe, for example, incorporated into a radical structure of 50 nm size or under, used in a scanning probe microscope (SPM) such as a near-field optical microscope, an atomic force microscope, and a tunnel microscope, and the like.

### EXAMPLE 2

Example 2 is directed to a structural example wherein the function of shape buffering layer and the function of light reflecting layer are provided by a single layer material.

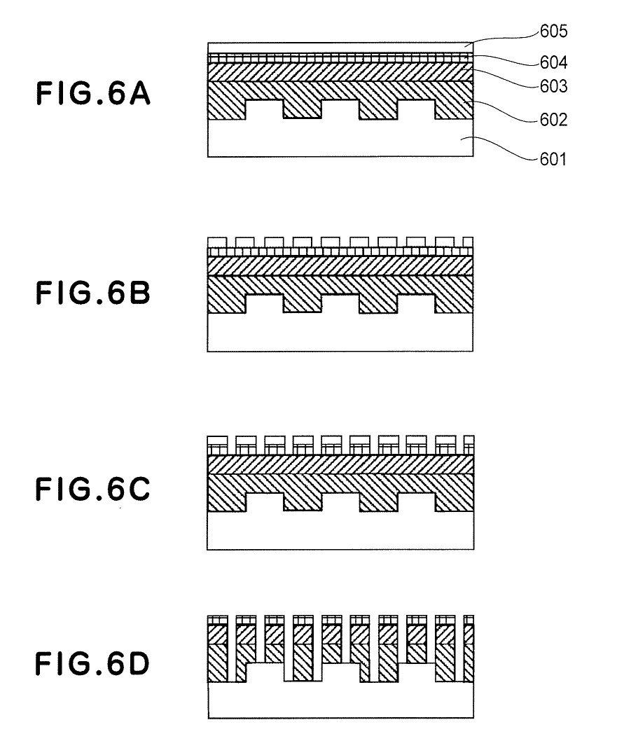

FIGS. 6A-6D are schematic views for explaining the structure according to this example.

First of all, a silicon substrate 601 having surface irregularity defined by a line-and-space of a depth 50 nm is prepared, and a film of 200 nm thickness is formed thereon through a spin coating process, using thiophene (conductive high polymer) solved in chloroform solvent, to provide a shape buffering and light reflecting layer 602.

Subsequently, upon the thiophene layer which is the shape buffering and light reflecting layer, a triple-layer resist is produced as an upper layer resist, in the following manner.

First, a positive resist is applied by a spin coating process to provide a lower layer 603 of the triple-layer resist, and then it is heated at 120° C. to remove the photosensitivity. The lower layer in this example has a thickness 120 nm.

Subsequently, a film of SiO₂ is formed with a thickness 20 nm, by a sputtering method, to provide an intermediate layer 604 of the triple-layer resist.

Furthermore, a chemical amplification type positive photoresist having sensitivity to i-line (wavelength 365 nm) of the bright line of an Hg lamp is formed by spin coating with a thickness 20 nm, to provide an upper layer 605 of the triple-layer resist (FIG. 6A).

Then, near-field exposure is carried out like Example 1 to the substrate having a resist film formed thereon as described, and development is carried out thereto by using an aqueous solution of 2.38% TMAH, whereby a pattern is produced on the upper layer 605 of the triple-layer resist 605 (FIG. 6B).

Subsequently, SiO₂ of the intermediate layer 604 is dry etched by using a mixed gas of SF₆ and CHF₃ (FIG. 6C). Then, by using a mixed gas of oxygen and argon, the lower layer 603 and the shape buffering and light reflecting layer 602 are dry etched, whereby a pattern is transferred thereto (FIG. 6D).

When a material having a function as shape buffering function and a function as light reflecting layer is used as described above, there is an advantageous feature to Example 1 that one film forming step can be omitted in relation to the formation of the shape buffering layer and the light reflecting layer and, furthermore, one dry etching step can be omitted.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2006-122995 filed Apr. 27, 2006, for which is hereby incorporated by reference.

What is claimed is:

1. A near-field exposure method in which a light blocking film with an opening having an opening width not greater than a wavelength size of exposure light is contacted to an object to be exposed and in which light from an exposure light source is projected on the light blocking film so that a pattern based on the opening of the light blocking film is formed on the object to be exposed, by use of near-field light produced at the opening, characterized in that:
the object to be exposed is prepared by a process that includes (i) a step of providing, upon a substrate having surface irregularity, a shape buffering layer so as to fill the surface irregularity thereof to thereby flatten the surface of the substrate, (ii) a step of providing, upon the shape buffering layer, a light reflecting layer for reflecting the exposure light, and (iii) a step of providing a photosensitive resist layer upon the light reflecting layer, and
the exposure is carried out to the object so prepared.

2. A method according to claim 1, wherein the surface irregularity of the substrate has a surface level difference 0.05 times or more as large as the wavelength of the exposure light within the photosensitive resist layer, and wherein, as a result of the flattening, the surface level difference of the surface irregularity of the substrate is substantially reduced to a value less than 0.05 times as large as the wavelength of the exposure light.

3. A method according to claim 1, wherein the photosensitive resist layer is provided by one layer of a multilayer-resist material having multiple layers.

4. A method according to claim 3, wherein the multilayer-resist material comprises a lower resist layer adapted to be removed by plasma etching, an intermediate layer formed on the lower resist layer and having resistance to plasma etching, and an upper resist layer that provides the photosensitive resist layer.

5. A method according to claim 3, wherein the multilayer-resist material comprises a lower resist layer adapted to be removed by plasma etching and an upper resist layer formed on the lower resist layer and having resistance to plasma etching.

6. A method according to claim 1, wherein the shape buffering layer has a thickness in a range from twice to ten times as large as the surface level difference of the surface irregularity of the substrate.

7. A method according to claim 1, wherein the light reflecting layer has a thickness in a range from 0.1 to 1 times as large as the thickness of the shape buffering layer.

8. A method according to claim 1, wherein the shape buffering layer is made of an organic material.

9. A method according to claim 1, wherein the light reflecting layer is made of one of a metal material, a semiconductor material and an organic material.

10. A device manufacturing method, including a process of producing a device by use of a near-field exposure method as recited in claim 1.

11. A near-field exposure method in which a light blocking film with an opening having an opening width not greater than a wavelength size of exposure light is contacted to an object to be exposed and in which light from an exposure light source is projected on the light blocking film so that a pattern based on the opening of the light blocking film is formed on the object to be exposed, by use of near-field light produced at the opening, characterized in that:
the object to be exposed is prepared by a process that includes (i) a step of providing, upon a substrate having surface irregularity, a function layer having a function as a shape buffering layer and a function as a light reflecting layer for reflecting the exposure light, so as to fill the surface irregularity thereof to thereby flatten the surface of the substrate, and (ii) a step of providing a photosensitive resist layer upon the function layer, and
the exposure is carried out to the object so prepared.

12. A method according to claim 11, wherein the surface irregularity of the substrate has a surface level difference 0.05 times or more as large as the wavelength of the exposure light within the photosensitive resist layer, and wherein, as a result of the flattening, the surface level difference of the surface irregularity of the substrate is substantially reduced to a value less than 0.05 times as large as the wavelength of the exposure light.

13. A method according to claim 11, wherein the photosensitive resist layer is provided by one layer of a multilayer-resist material having multiple layers.

14. A method according to claim 13, wherein the multilayer-resist material comprises a lower resist layer adapted to be removed by plasma etching, an intermediate layer formed on the lower resist layer and having resistance to plasma etching, and an upper resist layer that provides the photosensitive resist layer.

15. A method according to claim 13, wherein the multilayer-resist material comprises a lower resist layer adapted to be removed by plasma etching and an upper resist layer formed on the lower resist layer and having resistance to plasma etching.

16. A method according to claim 11, wherein the shape buffering layer has a thickness in a range from twice to ten times as large as the surface level difference of the surface irregularity of the substrate.

17. A method according to claim 11, wherein the light reflecting layer has a thickness in a range from 0.1 to 1 times as large as the thickness of the shape buffering layer.

18. A method according to claim 11, wherein the shape buffering layer is made of an organic material.

19. A method according to claim 11, wherein the light reflecting layer is made of one of a metal material, a semiconductor material and an organic material.

20. A device manufacturing method, including a process of producing a device by use of a near-field exposure method as recited in claim 11.
